(19) United States
(12) Patent Application Publication
(10) Pub. No.: US 2020/0185392 A1
(43) Pub. Date: Jun. 11, 2020

(54) 3D INTEGRATED CIRCUIT RANDOM-ACCESS MEMORY

(71) Applicant: Commissariat A L'Energie Atomique et aux Energies Alternatives, Paris (FR)

(72) Inventors: Adam MAKOSIEJ, Grenoble Cedex 09 (FR); Bastien GIRAUD, Grenoble Cedex 09 (FR); Jean-Philippe NOEL, Grenoble Cedex 09 (FR)

(73) Assignee: Commissariat A L'Energie Atomique et aux Energies Alternatives, Paris (FR)

(21) Appl. No.: 16/708,623

(22) Filed: Dec. 10, 2019

(30) Foreign Application Priority Data
Dec. 11, 2018 (FR) 18 72707

(51) Int. Cl. H01L 27/11; G11C 11/419; G11C 11/418

(52) U.S. Cl. CPC H01L 27/1104; G11C 11/418; H01L 27/1116; G11C 11/419

(57) ABSTRACT

A 3D-RAM memory comprising:
several memory cell arrays distributed in several superimposed memory layers;
a word line driver;
a row decoder coupled to the word line driver;
wherein the row decoder and the word line driver are arranged in a layer of command electronics which is separate from the memory layers,
and wherein, in each of the memory layers, each of the word lines is connected to an output of an electronic selection device arranged in the memory layer, a data input of which is connected to the word line driver, a command input of which is connected to the row decoder, and which is configured to let a signal of access to the transistors pass or not depending on the value of a received command signal.

### TECHNICAL FIELD

The technical field of the invention is that of RAM memories (random access memory) produced in the form of 3D (3 dimensions) integrated circuits, that is to say circuits comprising several superimposed layers, or produced in several superimposed electronic levels, and named 3D-RAM. The invention applies in particular to the production of SRAM (static random access memory) or DRAM (dynamic random access memory) memories, and in particular 3D-SRAM or 3D-DRAM.

### PRIOR ART

A planar, or 2D, integrated circuit is produced on a single substrate, the electronic components of this circuit being produced next to each other on this substrate.

A 3D integrated circuit corresponds to an electronic circuit the electronic components of which are distributed in several layers, or levels or substrates, which are distinct, superimposed one above the other and electrically connected to each other.

A 3D-RAM memory generally includes several superimposed layers, or levels, of RAM memory cells. Each memory cell corresponds to a memory element wherein 1 bit is stored. The memory cells are arranged in the form of arrays, that is to say lines and columns of memory cells. The memory cells arranged on a same line share a same word line controlling access to these memory cells. The memory cells arranged on a same column share the same bit line, and optionally a same complementary bit line.

Most often, each of the memory layers has the same design, or the same architecture, as a standard 2D or planar memory, as for example described in the document US 2015/019802 A1. In this document, several memory cell arrays are produced in several superimposed levels. The proposed memory architecture does not allow taking advantage of the superposition of the used layers.

The document “A High-speed, Low-power 3D-SRAM Architecture” by H. Nho and al., 2008 IEEE Custom Integrated Circuits Conference, describes a 3D-SRAM memory wherein the bit lines pass through the different layers of memory cells, each being connected to memory cells which are superimposed one above the other. Global bit lines are produced in a lower level, or layer, each of the global bit lines connecting several bit lines to memory detection amplifiers. However, this architecture does not allow obtaining an interesting gain in surface since the need to pass the bit lines in the memory cells results in a loss of surface of approximately 18% per memory cell compared to a standard SRAM memory cell.

The document “3D-Integrated SRAM Components for High-Performance Microprocessors” by K. Puttaswamy and al., IEEE Transactions on Computers, Vol. 58, No. 10, October 2009, describes other architectures of 3D-SRAM memories allowing to reduce the length of the interconnections in the memory. In the various proposed architectures, the operation of the memory implies that all the arrays of superimposed memory cells operate simultaneously, the selection of the desired data being performed after reading all the memory cell arrays. Such operation is therefore not optimal in terms of electrical consumption of the memory.

### DESCRIPTION OF THE INVENTION

There is therefore a need to provide a RAM memory produced in the form of a 3D integrated circuit whose architecture allows making connections between the different layers, or levels, of memory cells with short lengths, allowing to reduce the footprint, or the occupied surface, and thus maximize the density of memory cells for a given surface, and also improve the performance of the memory in particular in terms of electrical consumption of the memory.

For this purpose, a 3D-RAM memory is proposed comprising at least:
several memory cell arrays distributed in several superimposed memory layers and such that in each memory cell array, the memory cells arranged on a same line of the array are connected to a word line associated with said line of the array;
a word line driver;
a row decoder coupled to the word line driver;

wherein the row decoder and the word line driver are arranged in a layer of command electronics which is separate from the memory layers,

and wherein, in each of the memory layers, each of the word lines is connected to an output of an electronic selection device arranged in the memory layer comprising said word lines, a data input of which is connected to the word line driver, a command input of which is connected to the row decoder, and which is configured to let a signal received on its data input pass or not depending on the value of a signal received on its command input.

A 3D-RAM memory is also proposed comprising at least:
several memory cell arrays distributed in several superimposed memory layers and such that in each memory cell array, the memory cells arranged on a same line of the array are connected to a word line associated with said line of the array;
a word line driver;
a row decoder coupled to the word line driver;

Wherein:
the row decoder and the word line driver are arranged in a layer of command electronics which is separate from the memory layers,
in each of the memory layers, each of the word lines is connected to an output of an electronic selection device arranged in the memory layer comprising said word lines, a data input of which is connected to the word line driver, a command input of which is connected to the row decoder, and forming a commanded switch interposed between said word line and the word line driver and configured to let a signal received on its data input pass or not depending on the value of a selection signal of one of the memory layers received on its command input and outputted by the row decoder,
all the electronic selection devices arranged in a same memory layer are configured to receive on their command input a same selection signal of one of the memory layers, and
each electronic selection device further includes a bias element of the word line connected to the electronic selection device configured to ensure a bias of said word line at an electrical reference potential when the electronic selection device does not let the signal received on its data input pass.

In this 3D-RAM memory, each memory layer does not include a word line driver and a row decoder. The word line driver and the row decoder are arranged in a layer of command electronics which is separate from the layers wherein the memory cell arrays are formed. Thus, the space occupied by the word line driver and by the row decoder is freed from the memory layers, which allows reducing the surface occupied by the memory layers, and therefore the surface globally occupied by the 3D memory.

This displacement of the word line driver and of the row decoder in a layer different from the memory layers is possible thanks to the use of electronic selection devices which allow selecting the memory cells from one of the memory cell arrays wherein a read or write operation is performed.

This memory architecture therefore minimizes, within each of the memory layers, the electronic components other than those forming the memory cells, because in a memory layer, the electronic selection devices occupy less space than the word line driver and the row decoder. For a given surface, the storage capacity that can be obtained is therefore greater than that which can be obtained with the memory architectures of the prior art.

This memory architecture is adaptive and flexible, and can be easily adapted to different applications by adding different functionalities by adding additional functional blocks within the different layers of the memory.

Another advantage provided by this memory architecture is that the power network or mesh of the memory is similar to that of a conventional memory. This architecture can therefore be adapted to existing memories without modifying their power network, therefore creating no asymmetry or error during this adaptation.

The electronic selection devices act as a multiplexer commanded from the row decoder, since a datum sent from the word line driver is transmitted on the word lines of the desired memory cell array thanks to the selection made by the electronic selection devices (only the electronic selection devices connected to the desired array let the signal received on their data input pass). The electronic selection devices do not perform an amplification of the signals received on their input, and do not provide additional power to the signals received.

Each electronic selection device may form a commanded switch between one of the word lines and the word line driver. The electronic selection devices may be commanded by a level or a memory layer selection signal. A same level or memory layer selection signal may be transmitted to the electronic selection devices located on a same level or a same memory layer. Each level or memory layer selection signal may be transmitted on an electrically conductive line coupling the row decoder to the command inputs of the electronic selection devices of a same memory layer or a same level.

Furthermore, this 3D memory architecture also has the advantage of being made with short electrical connections and a high density of interconnections between the layers, favouring the obtaining of good performance.

In addition, since a read or write operation in a memory cell array is only performed in the desired array, the power consumption of the memory is reduced compared to the memories of the prior art wherein all the memory cell arrays are requested to perform a read or write operation intended for a single memory cell array.

This memory architecture is advantageously applied for applications using integrated memories.

The surface occupied by the memory corresponds to the surface occupied by the projection, in a plane parallel to the memory layers and to the layer of command electronics, of the stack formed by the memory layers and the layer of command electronics.

The electronic selection devices have a behaviour close to that of a multiplexer because thanks to these devices, data transmitted from the word line driver to all the memory cell arrays are only transferred to the word lines of a memory cell array selected thanks to the electronic selection devices.

Advantageously, the memory may be of the 3D-SRAM type, that is to say that the memory cells are of the SRAM type. With such SRAM-type memory cells, sharing the inputs/outputs and the command logic between the superimposed memory layers does not impact the dimensions of the stacked arrays due to the absence of the need for sequential refresh of each of the memory cells.

Alternatively, the memory may be of the 3D-DRAM type, that is to say that the memory cells are of the DRAM type.

Throughout the document, the expression “memory layer” designates a set of physical layers made of semi-conductive, dielectric and conductive materials, forming a single “tier”, including a portion named “Back- End” conventionally consisting of several levels of metal connections separated by dielectric layers and optionally connected by metal vias passing through these dielectric layers, and a portion named “Front-End” comprising, among others, a semi-conductive layer. The electronic selection devices forming elements for controlling the memory cells are for example made by means of transistors made on the surface of the semi-conductive layer. The memory cells, depending on their nature, will be made in one and/or the other of the “Front-End” or “Back-End” portions. Thus, SRAM-type memory cells will be made from transistors formed on the surface of the semi-conductive layer and connected together by metal connections placed in the “back-end”. Memory cells of the resistive memory type may be made by means of specific materials positioned in the “Back-End” portion, for example inside a dielectric layer.

In addition, the memory layers may be superimposed one above the other and may be arranged above the layer of command electronics. Alternatively, the memory layers may be arranged below the layer of command electronics.

Alternatively, it is possible that the layer of command electronics is arranged between two memory layers. This configuration has the advantage that the length of the interconnections between the electronics and command layer and the most distant memory layers is less than that obtained when the layer of command electronics is arranged under or on the memory layers.

Each electronic selection device may include a transfer gate (or “pass gate”) forming the commanded switch, an input of which forms the input of the electronic selection device, an output of which forms the output of the electronic selection device, and a command input of which forms the command input of the electronic selection device. The use of such a transfer gate is advantageous because it allows good maintenance of the levels 0 and 1 of the signals sent on the word lines. In addition, such a transfer gate needs only one command signal to operate.

Alternatively, each electronic selection device may include a first field effect transistor, or FET, forming the commanded switch and configured such that:
a first electrode, corresponding to the source or to the drain of the first transistor, forms the input of the electronic selection device,
a second electrode, different from the first electrode and corresponding to the drain or to the source of the first transistor, forms the output of the electronic selection device,
a gate forms the command input of the electronic selection device.

In addition, each electronic selection device, and more particularly each bias element, may include a second field effect transistor configured such that:
a first electrode, corresponding to the source or to the drain of the second transistor, is connected to the output of the electronic selection device,
a second electrode, different from the first electrode and corresponding to the drain or to the source of the second transistor, is connected to the electrical reference potential,
a gate is connected to a control circuit arranged in the layer of command electronics.

This second transistor may advantageously be turned on by the control circuit when no read or write operation is implemented in the memory cells associated with the word line to which the electronic selection device, which includes this second transistor, is connected.

The memory may further include global word lines, each global word line being connected to at least one input of an electronic selection device present in each of the memory layers.

The memory may be such that:
in each memory cell array, the memory cells arranged on a same column of the array may be connected to a bit line and a complementary bit line associated with said column of the array;
the bit lines may be connected to global bit lines such that each global bit line is connected to at least one bit line of each of the memory layers, and the complementary bit lines may be connected to global complementary bit lines such that each global complementary bit line is connected to at least one complementary bit line of each of the memory layers;
the global bit lines and the global complementary bit lines may be connected to detection amplifiers configured to read the memory cells.

According to a particular embodiment, each memory layer may include several memory cell arrays. This configuration is advantageous because it allows having a smaller space requirement, with equal storage capacity. This configuration also allows producing multiple access memory. Furthermore, by reducing the number of lines and columns of memory cells for each memory cell array, this reduces the capacities formed by the vias to which these memory cells are connected.

In each of the memory layers, when each memory layer includes several memory cell arrays, each of the bit lines and each of the complementary bit lines may be connected to a data input of a second electronic selection device arranged in the memory layer comprising said bit lines and complementary bit lines, one command input of which is connected to a read command circuit arranged in the layer of command electronics, an output of which is connected to one of the detection amplifiers, and which is configured to let a signal received on its data input pass or not depending on the value of a signal received on its command input.

When each memory layer does not include several memory cell arrays, in each of the memory layers, each of the bit lines and each of the complementary bit lines may be connected to an input of a second electronic selection device arranged in the memory layer comprising said bit lines and complementary bit lines, a command input of which may be connected to a read command circuit arranged in the layer of command electronics, an output of which may be connected to one of the detection amplifiers, and which may be configured to let a signal received on its data input pass or not depending on the value of a signal received on its command input.

The second electronic selection devices allow, when reading memory cells, connecting to the detection amplifiers only the bit lines and the complementary bit lines of the cells, thus avoiding also connecting the detection amplifiers to the other bit lines and to the other complementary bit lines. This reduces the capacities present at the input of the detection amplifiers.

In a particular embodiment, the memory may further include:
in each of the memory layers, at least one circuit for detecting PVT variations (or “Process, Voltage, Temperature” variations) and one circuit for applying bias voltages to transistor wells of memory cells,
in the layer of command electronics, a circuit for generating well bias voltages coupled to the PVT variation detection circuits and to the circuits for applying bias voltages to transistor wells of memory cells.

The memory architecture is well adapted to receive such circuits allowing to adapt the values of the bias voltages applied to the transistors wells of the memory cells depending on the PVT variations detected in the memory layers.

In a general manner, the layer of command electronics is well adapted to receive the circuits connected to the inputs and outputs of the memory, these circuits being generally bulky.

### BRIEF DESCRIPTION OF THE DRAWINGS

The present invention will be better understood upon reading the description of embodiments given in a purely indicative and non-limiting manner, with reference to the appended drawings wherein:

FIG. 1 shows a 3D-RAM memory according to a first embodiment;

FIGS. 2 and 3 show variant embodiments of an electronic selection device used in the 3D-RAM memory;

FIG. 4 shows a 3D-RAM memory according to a variant of the first embodiment;

FIG. 5 partially shows a 3D-RAM memory according to a second embodiment.

Identical, similar or equivalent portions of the different figures described below have the same reference numerals so as to facilitate the passage from one figure to another.

The different portions shown in the figures are not necessarily shown on a uniform scale, to make the figures more readable.

The different possibilities (variants and embodiments) must be understood as not being mutually exclusive and can be combined with one another.

### DETAILED DESCRIPTION OF PARTICULAR EMBODIMENTS

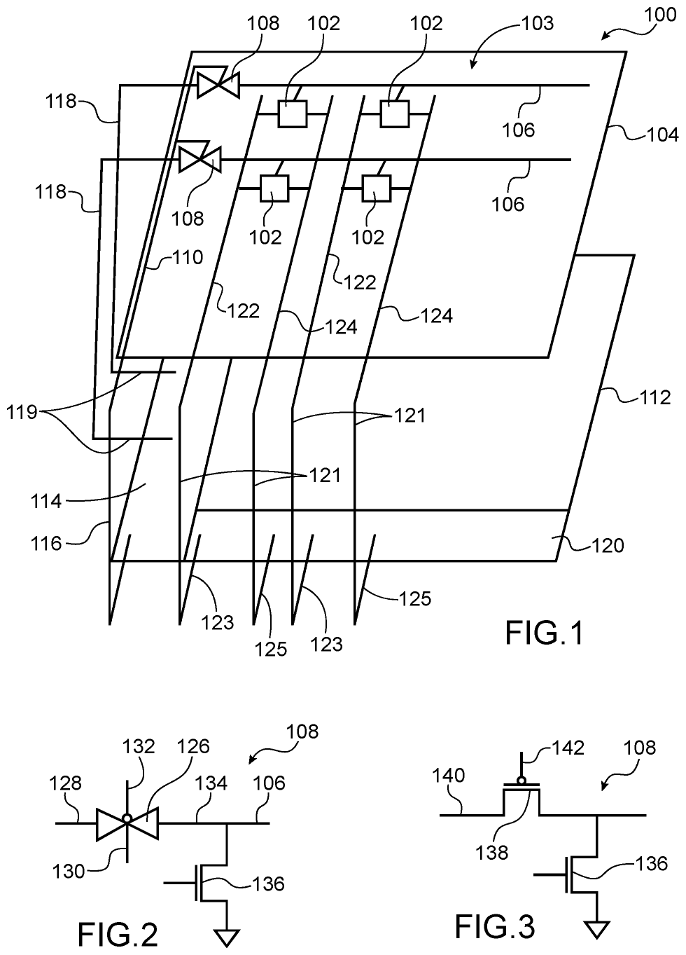

A 3D-RAM-type memory 100, according to a first embodiment and shown in FIG. 1, is described below.

The memory 100 includes several memory cell arrays 102, for example of the SRAM type and produced in several layers, named memory layers 104, superimposed one above the other. A single memory layer 104 is shown in FIG. 1. In addition, in FIG. 1, only four memory cells 102 are shown, distributed over two lines and two columns of an array 103 of memory cells 102.

In the first embodiment described here, all the memory cells 102 present in each memory layer 104 form a single array 103 of memory cells 102.

The memory cells 102 correspond for example to SRAM cells comprising 6 CMOS transistors (6T-SRAM). Alternatively, the memory cells 102 may correspond to other types of SRAM memory cells, comprising more or less than 6 transistors. The memory cells 102 correspond for example to the memory cells described in at least one of the following documents: “5T SRAM With Asymmetric Sizing for Improved Read Stability” by S. Nalam and al., IEEE Journal of Solid-State Circuits, Vol. 46, No. 10, October 2011; “An 8T-SRAM for Variability Tolerance and Low-Voltage Operation in High-Performance Caches” by L. Chang and al., IEEE Journal of Solid-State Circuits, Vol. 43, No. 4, April 2008; “A 32 kb 10T Sub-Threshold SRAM Array With Bit-Interleaving and Differential Read Scheme in 90 nm CMOS” by I. J. Chang and al., IEEE Journal of Solid-State Circuits, Vol. 44, No. 2, February 2009.

Alternatively, the memory cells 102 may correspond to DRAM cells comprising at least one storage capacity coupled to at least one access transistor.

In each memory layer 104, the access to each of the memory cells 102 arranged on a same line of the array 103 is commanded by an access signal sent on a word line 106 connected to the gates of the access transistors (not shown in FIG. 1) of each of these memory cells 102 arranged on a same line of the array 103.

In each memory layer 104, each word line 106 is connected to the output of an electronic selection device 108 by means of which the signal of access to the memory cells 102 of a line of the array 103 is sent on the word line 106. Each electronic selection device 108 is configured to let the access signal received on a data input of the electronic selection device 108 pass or not, depending on the value of a selection signal received on a command input of the electronic selection device 108.

In each memory layer 104, the electronic selection devices 108 have the role of either letting the access signals on the word lines 106 of this memory layer 104 pass when a read or write operation is carried out in memory cells 102 present on this memory layer 104, or not letting the access signals on the word lines 106 of this memory layer 104 pass when these access signals are intended to control the access to memory cells 102 of another memory layer 104, depending on the value of the selection signal received by all the electronic selection devices 108 of this memory layer 104.

In each memory layer 104, the command inputs of all the electronic selection devices 108 connected to the word lines 106 of the array 103 of this memory layer 104 are electrically connected to each other by means of a conductive line 110. Thus, thanks to a single command signal sent on the conductive line 110 of each of the memory layers 104, the access to the memory cells 102 of this memory layer 104 is authorized or not according to the value of this command signal.

In the first embodiment shown in FIG. 1, each electronic selection device 108 includes a transmission gate. In this case, each electronic selection device 108 includes a second command input, not shown in FIG. 1, complementary to the first command input corresponding to that shown in FIG. 1, and on which a second selection signal, of a value complementary to that of the selection signal sent on the first command inputs, is sent.

In addition to the memory layers 104 comprising the arrays 103 of memory cells 102, the memory 100 includes a layer 112, named layer of command electronics, wherein the various electronic command circuits of the memory 100 are made.

The memory 100 includes in particular a word line driver and a row decoder coupled to the word line driver, which are produced in the layer of command electronics 112. In FIG. 1, this word line driver and this row decoder are shown in the form of a single block referenced 114.

The conductive line 110 of each of the memory layers 104 is connected to the block 114 which outputs the selection signals which are each intended to control the electronic selection devices 108 from one of the memory layers 104. This connection is ensured, for each of the conductive lines 110, by a via 116 made through the stack of layers of the memory 100. In FIG. 1, this via 116 is shown outside the stack of layers of the memory 100 only for visibility reasons. Furthermore, although the memory 100 includes at least as many vias 116 as memory layers 104, only one via 116 is shown in FIG. 1.

Each electronic selection device 108 forms a commanded switch between one of the word lines 106 and the word line driver. The electronic selection devices 108 are commanded by a memory layer 104 selection signal. A same memory layer selection signal 104 is here transmitted to the electronic selection devices 108 located on a same memory layer 104. Each memory layer selection signal 104 is transmitted on one of the electrically conductive lines 1110 coupling the row decoder to the command inputs of the electronic selection devices 108 of a same memory layer 104.

The data inputs of the electronic selection devices 108 are also connected to the block 114 so that the word line driver outputs the access signals each intended to control access to the memory cells 102 of one of the lines of a memory cell 102 array 103 of one of the memory layers 104. These connections are ensured by vias 118 made through the stack of memory layers 100. In FIG. 1, the only visible via 118 is shown outside the stack of layers of the memory 100 only for visibility reasons.

Since the access signals are transmitted to all the memory layers 104 (the choice of the memory layer 104 concerned by these access signals being made thanks to the selection signals sent on the command inputs of the electronic selection devices 108), each via 118 is common to all the memory layers 104. Thus, a first via 118 is connected to the inputs of the electronic selection devices 108 connected to the first lines of the memory cells 102 of the arrays 103 present in all the memory layers 104, a second via 118 is connected to the inputs of the electronic selection devices 108 connected to the second lines of the memory cells 102 of the arrays 103 present in all the memory layers 104, etc. Each via 118 is connected to a global word line 119 formed in the layer of command electronics 112 and connected to the word line driver of the memory 100 and to which a word line 106 of each memory layer 104 is connected by means of an electronic selection device 108 and one of the vias 118.

Read or write data in the memory cells 102 are sent or received from an input/output circuit 120 made in the layer of command electronics 112, through vias 121 to which bit lines 122 and complementary bit lines 124 are connected. Each bit line 122 and each complementary bit line 124 is connected to the source or to the drain of one of the access transistors of the memory cells 102 of a same column of one of the arrays 103 of memory cells 102. The input/output circuit in particular includes detection amplifiers used for reading data.

Given that the read or write data are transmitted to all the memory layers 104 (the choice of the memory layer 104 concerned by these access signals being made thanks to the selection signals sent on the command inputs of the electronic selection devices 108), each via 121 is common to all of the memory layers 104. Thus, a first via 121 is connected to the bit lines 122 connected to the first columns of the memory cells 102 of the arrays 103 present in all the memory layers 104, a second via 121 is connected to the complementary bit lines 124 connected to the first columns of the memory cells 102 of the arrays 103 present in all the memory layers 104, a third via 121 is connected to the bit lines 122 connected to the second columns of the memory cells 102 of the arrays present in all the memory layers 104, etc. Each via 121 is connected to a global bit line 123 or a global complementary bit line 125 connected to the input/output circuit 120 of the memory 100 and to which a bit line 122 or a complementary bit line 124 of each memory layer 104 is connected.

The memory 100 also includes other electronic control/command elements and circuits made in the command electronic layer 112, such as for example a read and write assist circuit, a bit line decoding circuit, an error correction code circuit, a redundancy management circuit, etc. Because these elements are made in the electronic command layer 112, this allows reducing the surface necessary for producing the memory 100 because these elements are not located in the memory layers 104.

In the first embodiment of the memory 100 shown in FIG. 1, each electronic selection device 108 corresponds to a transfer gate. The electronic selection devices 108 may however be produced by components other than transfer gates.

FIG. 2 shows a first variant embodiment of an electronic selection device 108. According to this first variant, the electronic selection device 108 includes a transfer gate 126. A data input 128 of the transfer gate 126 is intended for be connected to one of the vias 118. A first command input 130 of the transfer gate 126 is intended to be connected to one of the conductive lines 110 on which a memory layer 104 selection signal is sent, and a second command input 132 of the transfer gate 126 is intended to receive a second selection signal of a value complementary to that of the selection signal sent on the first command input 130. The transfer gate 126 includes an output 134 connected to the drain of an NMOS transistor 136. A hold signal is intended to be applied on the gate of the NMOS transistor 136 to turn on the NMOS transistor 136 when no read or write operation is implemented in the memory cells 102 associated with the word line 106 to which the electronic selection device 108 is connected.

The hold signal applied on the gate of the NMOS transistor 136 may be common to all the electronic selection devices 108 present on a same memory layer 104. Thus, as soon as a read or write operation is implemented in a memory cell 102 of a memory layer 104, the NMOS transistors 136 of all the electronic selection devices 108 present on this memory layer 104 are turned off. When no read or write operation is carried out in one of the memory cells 102 of this memory layer 104, the NMOS transistors 136 of all the electronic selection devices 108 present on this memory layer are turned on. According to a particular exemplary embodiment, the hold signals applied to the gates of the NMOS transistors 136 may correspond to the second selection signals sent on the second command inputs 132 of the transfer gates 126 to which the NMOS transistors 136 are coupled.

According to another variant, the NMOS transistor 136 gate may receive, from the layer of command electronics 112, a signal of a value complementary to that of the signal circulating on the word line 106 associated with the electronic selection device including the NMOS transistor 136. Thus, in a memory layer 104, only the NMOS transistor 136 associated with the line of memory cells 102 wherein a read or write operation is implemented is turned off, the other NMOS transistors 136 present on the memory layer 104 and which are associated with the other lines of memory cells 102 being turned on.

FIG. 3 shows a second variant embodiment of the electronic selection devices 108 present in the memory 100. According to this second variant, the electronic selection device 108 includes a PMOS transistor 138. A data input 140, connected to the source of the PMOS transistor 138, is intended to be connected to one of the vias 118. A command input 142, connected to the gate of the PMOS transistor 138, is intended to be connected to one of the conductive lines 110 on which a memory layer 104 selection signal is sent. The drain of the PMOS transistor 138 is connected to the drain of the NMOS transistor 136. As in the first variant described above, a hold signal is intended to be applied on the gate of the NMOS transistor 136 to turn the NMOS transistor 136 on when no read or write operation is carried out in the memory cells 102 associated with the word line 106 to which the electronic selection device 108 is connected.

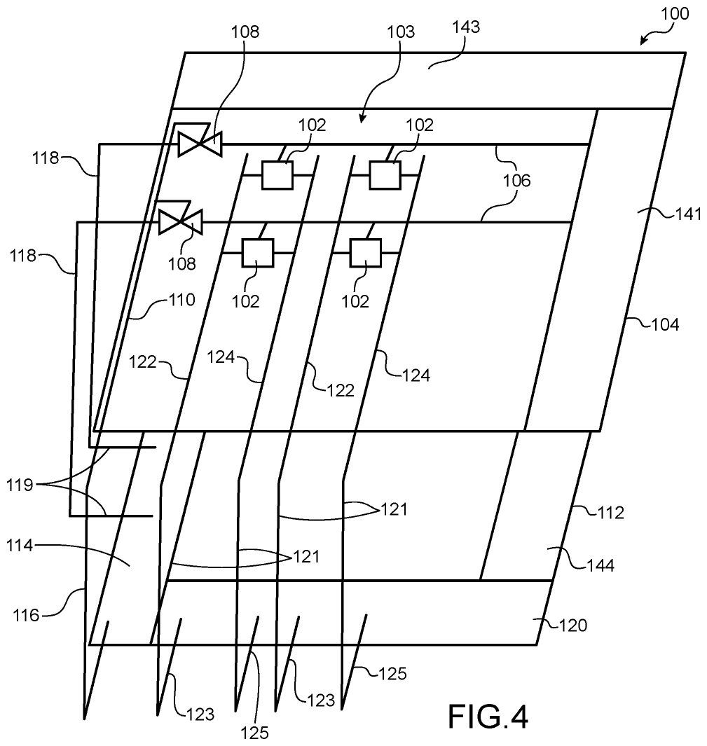

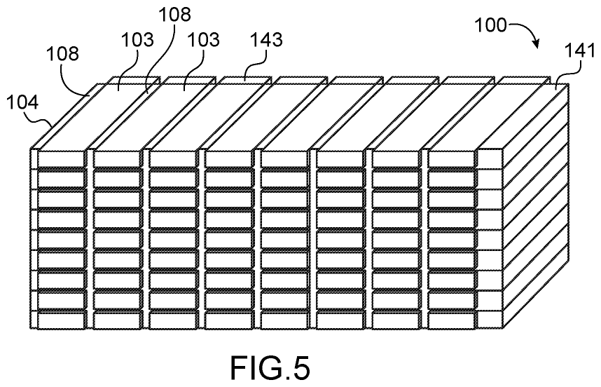

The memory 100 according to a variant of the first embodiment is described below and shown in FIG. 4.

In this variant, the memory 100 includes all the elements of the memory 100 previously described in connection with FIG. 1. In addition to these elements, the memory 100 also includes, in each of the memory layers 104, at least one PVT (“Process Voltage Temperature”) variation detection circuit 141, as well as a circuit for applying a well bias voltage 143 allowing to apply the desired voltage to the wells of the memory cell 102 transistors. In each memory layer 104, this well bias voltage may for example be the same for all the memory cells 102 of the memory layer 104, or applied independently for each of the columns of the memory cells 102 or else independently for groups of adjacent memory cells 102, for example for each line of memory cells 102.

The memory 100 according to this variant also includes, in the layer of command electronics 112, a circuit for generating well bias voltages 144 coupled to the PVT variation detection circuits 141 present in the memory layers 104.

The PVT variation detection circuits 141 generate a code which is used to select one from several levels of well bias voltage. The voltage level desired and generated by the well bias voltage generation circuit 144 may then be applied by the well bias voltage application circuits 143 on the wells of the transistors with which these circuits are associated.

A second embodiment of the memory 100 is described below in connection with FIG. 5.

As in the first embodiment, the memory 100 is produced in the form of a stack of several memory layers 104 and of a layer of command electronics 112. In FIG. 5, only the memory layers 104 are shown (nine memory layers 104 in the example of FIG. 5).

Unlike the first embodiment wherein a single array 103 of memory cells 102 is produced in each of the memory layers 104, each memory layer 104 of the memory 100 according to this second embodiment includes several arrays 103 of memory cells 102 arranged next to each other. In the example shown in FIG. 5, each memory layer 104 includes eight arrays 103 of memory cells 102. As an example, each array 103 may include 32 columns of memory cells 102 such that each line of memory cells 102 forms a 32-bit word. The number of lines of memory cells 102 of each array 103 is selected according to the performance required for the memory 100 (the greater the number of lines of memory cells, the greater the access times to the memory cells.)

In the memory 100 shown in FIG. 5, the write and read operations in the memory cells 102 of each array 103 are implemented independently of the read or write operations carried out in the other arrays 103 of memory cells 102. In each memory layer 104, each array 103 of memory cells 102 includes word lines which are not shared with the other arrays 103 of memory cells 102 of the memory layer 104. For each array 103, each word line is connected to an electronic selection device 108 to which the other word lines of the array and of the other arrays present in the memory layer 104 are not connected. In the example shown in FIG. 5, each array 103 of memory cells 102 is juxtaposed with the electronic selection devices 108 to which the word lines of the array 103 are connected.

This independence of the electronic selection devices 108 between the different arrays 103 present in a same memory layer 104 allows addressing the arrays 103 independently of each other, and in particular of the arrays 103 present in different memory layers 104 and/or in a same memory layer 104 simultaneously.

As in the first embodiment, each memory layer 104 includes a PVT variation detection circuit 141, as well as well bias voltage application circuits 143 such that each array 103 is coupled to at least one of these circuits 143. A well bias voltage generation circuit 144, not shown in FIG. 5, is produced in the electronic command layer of the memory 100.

Although not shown in FIG. 5, the memory 100 also includes vias 116 and 118 allowing to connect together the command and data inputs of the electronic selection devices 108 formed in the different memory layers 104 and which are connected to arrays 103 of memory cells superimposed one above the other.

The memory 100 also includes vias 121, not shown in FIG. 5, to which the bit lines and the complementary bit lines formed in the memory layers 104 are connected and forming global bit lines and global complementary bit lines connected to an input/output circuit present in the electronic command layer of the memory 100.

The variant embodiments of the electronic selection device previously described in connection with FIGS. 2 and 3 may apply to the memory 100 according to this variant of the first embodiment.

It should be noted that the types, n or p, of the transistors present in the embodiments described above may be different from those previously described.

Regardless of the embodiment of the memory 100, other electronic circuits performing for example command, storage or calculation functions may be integrated into the memory 100, in particular in the layer of command electronics 112.

Regardless of the embodiment of the memory 100, the memory 100 may include one or more layer(s) of command electronics.

In the embodiments previously described, the layer of command electronics is arranged under the memory layers 104. Alternatively, it is possible that the layer(s) of command electronics is/are arranged between two memory layers 104, or above the memory layers 104.

In the embodiments described above, for n memory layers 104, n electronic selection devices 108 are connected to a same via 118. Alternatively, it is possible to have m electronic selection devices 118 to which these n electronic devices 108 are connected, with m and n whole numbers such as m<n, so that at least one of these vias 118 is connected to at least two electronic selection devices 118.

1. A 3D-RAM memory comprising at least:
several memory cell arrays distributed in several superimposed memory layers and such that in each memory cell array, the memory cells arranged on a same line of the array are connected to a word line associated with said line of the array;
a word line driver;
a row decoder coupled to the word line driver;
wherein:
the row decoder and the word line driver are arranged in a layer of command electronics which is separate from the memory layers,
in each of the memory layers, each of the word lines is connected to an output of an electronic selection device arranged in the memory layer comprising said word lines, a data input of which is connected to the word line driver, a command input of which is connected to the row decoder, and forming a commanded switch interposed between said word line and the word line driver and configured to let a signal received on its data input pass or not depending on the value of a selection signal of one of the memory layers received on its command input and outputted by the row decoder,
all the electronic selection devices arranged in a same memory layer are configured to receive on their command input a same selection signal of one of the memory layers, and
each electronic selection device further includes a bias element of the word line connected to the electronic selection device configured to ensure a bias of said word line at an electrical reference potential when the electronic selection device does not let the signal received on its data input pass.

2. The 3D-RAM memory according to claim 1, wherein the memory layers are superimposed one above the other and are arranged above the layer of command electronics, or wherein the layer of command electronics is arranged between two memory layers.

3. The 3D-RAM memory according to claim 1, wherein each electronic selection device includes a transfer gate forming the commanded switch, an input of which forms the input of the electronic selection device, an output of which forms the output of the electronic selection device, and a command input of which forms the command input of the electronic selection device.

4. The 3D-RAM memory according to claim 1, wherein each electronic selection device includes a first field effect transistor forming the commanded switch and configured such that:
a first electrode, corresponding to the source or to the drain of the first transistor, forms the data input of the electronic selection device,
a second electrode, different from the first electrode and corresponding to the drain or to the source of the first transistor, forms the output of the electronic selection device,
a gate forms the command input of the electronic selection device.

5. The 3D-RAM memory according to claim 3, wherein each bias element includes a second field effect transistor configured such that:
a first electrode, corresponding to the source or to the drain of the second transistor, is connected to the output of the electronic selection device,
a second electrode, different from the first electrode and corresponding to the drain or to the source of the second transistor, is connected to the electrical reference potential,
a gate is connected to a control circuit arranged in the layer of command electronics.

6. The 3D-RAM memory according to claim 4, wherein each bias element includes a second field effect transistor configured such that:
a first electrode, corresponding to the source or to the drain of the second transistor, is connected to the output of the electronic selection device,
a second electrode, different from the first electrode and corresponding to the drain or to the source of the second transistor, is connected to the electrical reference potential,
a gate is connected to a control circuit arranged in the layer of command electronics.

7. The 3D-RAM memory according to claim 1, further including global word lines, each global word line being connected to at least one input of an electronic selection device present in each of the memory layers.

8. The 3D-RAM memory according to claim 1, wherein:
in each memory cell array, the memory cells arranged on a same column of the array are connected to a bit line and a complementary bit line associated with said column of the array;
the bit lines are connected to global bit lines such that each global bit line is connected to at least one bit line of each of the memory layers, and the complementary bit lines are connected to global complementary bit lines such that each global complementary bit line is connected to at least one complementary bit line of each of the memory layers;
the global bit lines and the global complementary bit lines are connected to detection amplifiers arranged in the layer of command electronics and configured to read the memory cells.

9. The 3D-RAM memory according to claim 1, wherein each memory layer includes several memory cell arrays.

10. The 3D-RAM memory according to claim 8, wherein, in each of the memory layers, each of the bit lines and each of the complementary bit lines is connected to an input of a second electronic selection device arranged in the memory layer comprising said bit lines and complementary bit lines, a command input of which is connected to a read command circuit arranged in the layer of command electronics, an output of which is connected to one of the detection amplifiers, and which is configured to let a signal received on its data input pass or not depending on the value of a signal received on its command input.

11. The 3D-RAM memory according to claim 1, further including:
in each of the memory layers, at least one circuit for detecting process, voltage and temperature variations and one circuit for applying bias voltage to transistor wells of memory cells,
in the layer of command electronics, a circuit for generating well bias voltages coupled to process, voltage and temperature variation detection circuits and to the circuits for applying bias voltages to transistor wells of memory cells.

12. The 3D-RAM memory according to claim 1, wherein the memory cells are of the SRAM type.
